(19) United States
(12) Patent Application Publication
(10) Pub. No.: US 2012/0025848 A1
(43) Pub. Date: Feb. 2, 2012

(54) Device for Transmitting and/or Receiving Electromagnetic RF Signals, and Measurement Instrument and Machine-Tool Monitoring Device with such a Device

(75) Inventors: Juergen Hasch, Stuttgart (DE); Alexander Werner Hees, Bietigheim-Bissingen (DE)

(73) Assignee: Robert Bosch GmbH, Stuttgart (DE)

(21) Appl. No.: 13/148,121

(22) PCT Filed: Jan. 11, 2010
(86) PCT No.: PCT/EP2010/050190

§ 371 Date: Oct. 24, 2011

(30) Foreign Application Priority Data
Feb. 5, 2009 (DE) 10 2009 000 644.3

(51) Int. Cl. G01N 22/04; G01R 27/04; H01Q 19/10; H01Q 9/16; H01Q 1/50

(52) U.S. Cl. 324/640; 343/793; 343/821; 343/818; 324/639

(57) ABSTRACT

A device for transmitting and/or receiving electromagnetic RF signals, in particular a UWB antenna, has a planar, ultra-wideband antenna structure made of a plurality of dipole elements. Each dipole element comprises two poles having substantially elliptical base shapes. A measuring machine, in particular a locating and/or material identifying device for identifying objects encased in a medium and/or for identifying material parameters, in particular the moisture of a material, has at least one UWB sensor comprising at least one device for transmitting electromagnetic RF signals. A machine tool monitoring device has a detecting device for detecting the presence of a material type, in particular of tissue, in a machine tool working area, and has a working mechanism wherein the detecting device comprises a sensor unit having at least one device for transmitting electromagnetic RF signals.

### PRIOR ART

### Disclosure of the Invention

The invention assumes a device for transmitting and/or receiving electromagnetic RF signals, in particular a UWB antenna.

In this context, an ultra-wideband (UWB) antenna should in particular be understood to mean an antenna that can be used to generate, transmit, receive and/or evaluate an ultra-wideband radar signal. In particular, an “ultra-wideband (or UWB) radar signal” should be understood to mean an electromagnetic signal that has a useful frequency range with a mid-frequency in the frequency range between approximately 1 GHz and 15 GHz and a frequency bandwidth of at least 500 MHz.

For ultra-wideband applications in the frequency range between approximately 1 GHz and 15 GHz, there are a multiplicity of antenna geometries for very different applications.

In the field of communication, use is preferably made of omnidirectional antennas, in which an electromagnetic wave with constant power is emitted or received e.g. in a specific plane in the azimuthal direction. However, by contrast, emission should, in a targeted fashion, be in one direction in the case of radar applications. Thus, antennas with directivity, i.e. directional antennas are used in place of omnidirectional antennas.

By way of example, the tapered slot antenna according to A. Hees, J. Hasch and J. Detlefsen (“Tapered Slot Antenna with Dielectric Rod and Metallic Reflector”, 2008 IEEE International Symposium on Antennas and Propagation, San Diego, USA, July 2008, and “Corrugated Tapered Slot Antenna with Dielectric Rod and Metallic Reflector”, 2008 IEEE International Conference on Ultra-Wideband, Hannover, Germany, September 2008) is known as an ultra-wideband antenna type with directivity.

Furthermore, UWB antennas with a three-dimensional dipole and an additional dielectric rod are known in order to achieve further increased directivity. In this respect, see e.g. M. Blech, T. Eibert in “A Directive Ultra-Wideband Dipole Antenna with Dielectric Rod and Reflector”, 2nd International ITG Conference on Antennas, 2007 and T. F. Eibert, “Ultra-breitbandige Dipolantenne mit dielektrischem Stab and Reflektor” [“Ultra-wideband dipole antenna with dielectric rod and reflector”], German patent application DE 10 2006 036 325.6-55, August 2006.

A flat and ultra-wideband antenna whose aperture configuration is generated by supplying individual rectangular dipole elements on a substrate is known from R. N. Foster, T. W. Hee, P. S. Hall, “Ultra wideband dual polarised arrays” IEEE International Workshop on Antenna Technology: Small Antennas and Novel Metamaterials, pp. 219-222, 2006.

### Object of the Invention

The object on which the invention is based consists in improving the antennas known from the prior art.

### Advantages of the Invention

In order to be able to establish the dielectric constant of a material (e.g. concrete wall, wood, plastic, human tissue, etc.) and thus also establish, for example, the presence of a hand or the dampness of a wall, a sufficiently large frequency bandwidth and strong focusing (directivity) of the electromagnetic waves emitted by an antenna are required for the application of a broadband (UWB) radar method. A strongly directed antenna is advantageous particularly in the case of thick and damp samples, in which the dielectric losses in the material can become very high. On the other hand, a very small measurement region or measurement spot can also serve only to determine, in a targeted fashion, the dielectric constant of a material in a defined region.

These materials are registered by the antenna by a change in its input impedance or detuning, i.e. the materials are in the emitting near-field of the antenna. In the case of protection sensors of electric tools, the protection zone e.g. directly in front of a saw blade can be observed by the measurement region or by the measurement spot.

The device according to the invention for transmitting and/or receiving electromagnetic RF signals, consists of an, in particular planar, ultra-wideband (UWB) antenna structure, consisting of a plurality of dipole elements, wherein each dipole element has two poles with a substantially elliptic basic shape.

Such an antenna structure advantageously allows a low overall height with, at the same time, a significantly reduced tendency for over-coupling the emitter elements (dipoles). Compared to a broadband slot antenna, which can have an installation depth of 80 mm or more in the frequency range between 2.2 and 9 GHz, the depth in the antenna concept according to the invention is fixed by the spacing between the emitter elements (dipoles) and the reflector element and usually lies in the region of λ/4 at the mid-frequency of the antenna. In the same, aforementioned frequency range this results in a relatively short overall height of approximately 10 mm.

In principle, broadband dipoles with a rectangular or triangular basic shape, in particular with such an elongated basic shape, are also feasible.

A broadband and, moreover, dual polarizable antenna structure can advantageously be implemented by there being a plurality of emitter elements (dipoles). To this end, the dipoles can be arranged in two preferred directions and be supplied by an appropriate electric signal.

A dual polarized antenna can easily be implemented by adding further dipole elements, rotated by 90°, to the arrangement. The arrangement of the individual dipole elements (e.g. two dipoles, which are rotated by 90 degrees with respect to one another, are supplied in their common center or are offset with respect to one another and have no common supply point) can be selected in an arbitrary fashion in this case.

A further advantage of the device according to the invention for transmitting and/or receiving electromagnetic RF signals lies in the targeted setting of the current configuration for each individual dipole element. Skillful selection of the amplitude and phase relations amongst the dipoles themselves allows a targeted aperture configuration of the entire antenna structure to be undertaken. The aperture angle of the antenna in the E- and H-plane in the far field, the size of the measurement spot and the side-lobe attenuation can be influenced thereby.

A reflector is provided for improving the directivity of the antenna in a half-plane. Such an—in particular metallic—reflector is then advantageously attached counter the main emission direction of the device and can be positioned below the structure of the emitting dipoles.

By way of example, the reflector can be embodied as a substantially planar, metallic reflector element, or else as a metalized layer of a printed circuit board.

Then, the reflector element should in this case be substantially perpendicular to the main emission direction of the device.

A further advantage of this antenna geometry lies in embodying the reflector by means of a printed circuit board, wherein the electrically conductive plane is implemented by a copper surface (e.g. V_{cc} or GND) situated on the top or bottom layer. Components for implementing a sensor (signal evaluation) and the actuation of the individual dipole elements can be arranged on the circuit board in a very space-saving fashion. This dispenses with connection cables from the antenna structure to evaluation electronics.

The reflector can advantageously be placed even closer to the dipole elements by implementing the reflector in a magnetically conductive fashion (reflection factor +1) for certain frequency bandwidths by means of electromagnetic band gap structures (EBG structures). Here, the reflected wave is in phase with the approaching one, as a result of which the spacing can be reduced. However, a disadvantage is an increase at each individual dipole in the input reflection factor.

The individual dipole elements are supplied via suitable baluns, such as a tapered microstrip balun and/or a Marchand balun (microstrip line on a slotline transition). The baluns can either be attached between the dipole elements on the substrate and the reflector, below the reflector, integrated onto a circuit board, which simultaneously serves as a reflector, or be embodied as a separate component.

Thus the antenna according to the invention is advantageously suitable as a component of a sensor for a measurement instrument, such as e.g. a localization and/or material determination instrument.

Moreover, the antenna according to the invention is likewise advantageously suitable as a component of a sensor of a machine-tool monitoring device.

In the case of protection sensors in electric tools, the measurement region or the measurement spot can describe and observe the protection zone e.g. directly in front of the saw blade of a circular or band saw.

The formation of array cells, which respectively consist of a plurality of dipoles, allows large-area monitoring of the workspace of a machine tool, e.g. a saw.

Further advantages emerge from the embodiments and developments of the antenna according to the invention as per the dependent claims.

### DRAWING

The drawing illustrates exemplary embodiments of the device according to the invention, a measurement instrument according to the invention and a machine-tool monitoring device according to the invention. The description, the associated figure and the claims contain a combination of a number of features. A person skilled in the art will also consider these features individually, in particular the features of different exemplary embodiments as well, and will combine these to form meaningful additional combinations.

In detail:

FIG. 1 shows a plan view of a schematic illustration of the shape of the dipoles and the basic arrangement of the dipoles of the device according to the invention,

FIG. 2 shows a perspective illustration of the support structure with dipoles according to the invention and an associated reflector means,

FIG. 3 shows a perspective illustration of the device according to the invention including parts of the supply electronics,

FIG. 4 shows an exemplary embodiment of a localization and material determination instrument according to the invention with a device according to the invention, and

FIG. 5 shows an exemplary embodiment of a machine-tool monitoring device with a device according to the invention.

### DESCRIPTION OF EXEMPLARY EMBODIMENTS

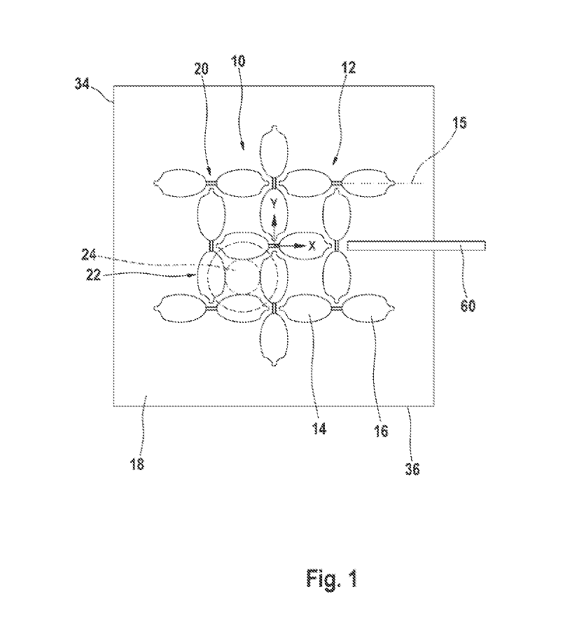

FIG. 1 shows, in a plan view, a possible arrangement of individual dipole moments, i.e. the antenna structure 10 of a device according to the invention for transmitting and/or receiving electromagnetic RF signals. The antenna structure 10 consists of a plurality of emitter elements in dipole form. The dipoles 12, also referred to as dipole elements in the following text, are applied to a support element 18 as metallic structures and each have an axis 15 along which the poles are arranged. The support element 18 in the exemplary embodiment in FIG. 1 has a planar structure and can for example be a printed circuit board (circuit board) with an appropriate insulation layer. In a further embodiment, the dipole array can also be implemented on e.g. a dielectric film (e.g. Kapton by DuPont) instead of on a circuit board. The flexibility of such films leads to a whole host of advantages of the antenna structure according to the invention.

The two poles 14 and 16 of the dipoles 12 each have a substantially elliptic, areal structure, which likewise is planar in the shown exemplary embodiment. In each case, there is a slight deviation from the pure elliptic shape at the axial ends of the dipoles 12. In order firstly to keep the axial extent of the dipoles 12 as large as possible but secondly ensure a minimum spacing between the dipoles 12, the curvature of the shape of the poles 14 and 16 of the dipoles 12 switches from a convex shape to a concave shape at the axial ends thereof. In particular, the concave curvature at the axial ends of the poles 14 and 16 corresponds to the convex curvature at the inner, i.e. facing the supply point 20, end of the poles. This makes it possible to maintain an—in particular constant—spacing between the axial and inner ends of different poles and hence between the dipoles 12. However, this deviation in shape from the pure elliptic shape at the respective axial end of the poles 14 and 16 should be considered “substantially elliptic” within the scope of the subject matter according to the invention. By maintaining a minimum spacing between the poles of the dipoles, it is possible to reduce and optimize the crosstalk or over-coupling of the dipoles.

The elliptic shape of the poles 14, 16 of the dipoles 12 of the antenna structure 10 advantageously leads to strong suppression of side lobes in the emission characteristic of the antenna. The elliptic basic shape of the dipoles 12, which means a relatively large axial extent with a significantly reduced width of the emitter elements, leads to an advantageous current configuration of these electrodes, and so no higher modes are excited, which is the case, for example, in the case of the antenna structure, based on a rhomboid grid, according to R. N. Foster, T. W. Hee, P. S. Hall, (“Ultra wideband dual polarised arrays” IEEE International Workshop on Antenna Technology: Small Antennas and Novel Metamaterials, pp. 219-222, 2006).

Moreover, the elliptic design of the emitter elements allows an improvement in the bandwidth of the antenna structure 10 because the lower cut-off frequency of the antenna is reduced as the emitter element becomes longer. A dielectric, e.g. a further substrate with the same material thickness, additionally applied to the dipole elements 12 can further lower the lower cut-off frequency of the dipoles 12 and thus further increase the bandwidth of the antenna structure 10. Whilst having the same dipole dimensions, the structure appears longer in electric terms.

The dipoles 12 of the antenna structure 10 are arranged in two preferred directions. The preferred directions X, Y in the exemplary embodiment according to FIG. 1 are arranged orthogonally with respect to one another, and so the dipoles 12 are also arranged perpendicular to one another in two groups. By way of example, the preferred directions can be defined by the limiting geometry, such as the limiting edges 34, 36 of the support element 18.

In the exemplary embodiment in FIG. 1, the antenna structure has five dipoles that are oriented in the X-direction and four dipoles that are oriented in the Y-direction. Such a number and subdivision substantially represents an optimum configuration in respect of the compactness and the possible monitoring region of the device according to the invention.

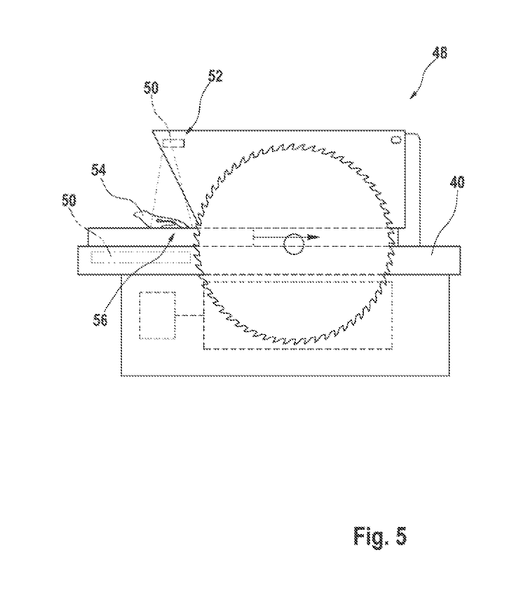

However, when the device according to the invention is integrated or used in an identification unit of a machine-tool monitoring device, as illustrated in e.g. FIG. 5, a preferred direction can also be prescribed by the orientation of the work means or the tool. Thus, by way of example, one preferred direction can be the advance direction of a saw. In order to clarify these circumstances, FIG. 1 additionally indicates, in a schematic fashion, a work means 60 in the form of a saw blade. Here, the antenna structure 10 is arranged directly in front of the saw blade 60. In FIG. 1, the work means 60 has only been sketched for clarifying one application option and restricts neither the embodiment of the antenna structure according to the invention nor the application options of the claimed device.

The dipole elements 12 of the antenna structure according to the invention are arranged such that four poles of four adjacent dipoles substantially form an annular structure 22 in each case. Here, the annular structure need not necessarily be circular. In particular, the arrangement according to the invention of the dipole elements 12 has a type of ring structure 22 that generates an “eye” 24, i.e. this results in a—not insignificant—region of the antenna structure 10 that is not occupied by a metallic electrode of an emitter element. Compared to quadratic or rhomboidal dipole elements, this region of non-electrode coverage has a significantly larger embodiment. The parallel spacing between the dipole elements generated thus advantageously prevents over-coupling of the signals from various dipoles.

Thus, this allows a simple implementation of a dual polarized antenna, in which the dipoles, which are rotated by 90 degrees or aligned along the two preferred directions X and Y, are supplied with an appropriate signal. The dipoles from one preferred direction then respectively emit into one polarization direction. Here, it is possible to select the supply of the individual dipole elements almost arbitrarily (e.g. two dipoles that are rotated by 90 degrees to one another are supplied at their common center or are arranged offset to one another and do not have a common supply point).

Advantageously, it is possible to set the current configuration of an individual dipole element in a targeted fashion. Skillful selection of the amplitude and phase relations amongst the dipoles allows a targeted aperture configuration of the entire antenna/antenna structure to be undertaken. The aperture angle of the antenna in the E- and H-plane in the far field, the size of the measurement spot and also the side-lobe attenuation can be influenced thereby.

The monitoring region implemented by the antenna structure or the array from FIG. 1, referred to as array cell 32 below, can be extended by duplicating or multiplying this basic structure. It is possible to supply individual dipole elements or individual dipole cells in a targeted fashion as a result of a plurality of array cells placed next to one another and a combinatory actuation logic. The superposition of the fields generated by the dipoles result in a new measurement region that, in particular, can also be changed by a non-stationary actuation, for example it can follow a workpiece.

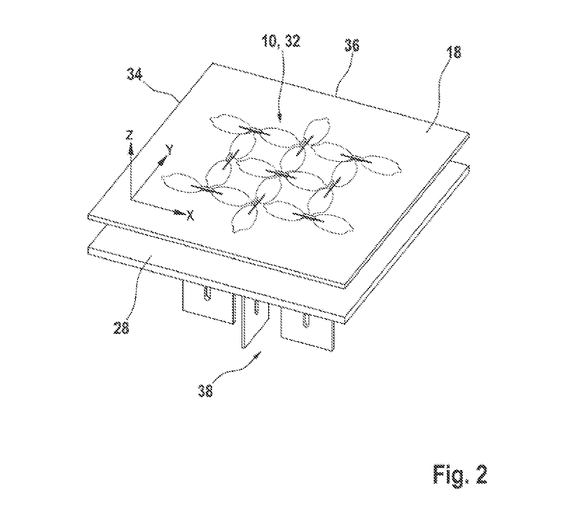

FIG. 2 shows a perspective illustration of the device according to the invention with a support element 18, an antenna structure 10 and an additional reflector element 28, which is arranged below the antenna structure 10, i.e. counter to the main emission direction Z. The reflector element 28 can be a metallic or metalized plate. In the exemplary embodiment of FIG. 2, the reflector element 28 is a printed circuit board (circuit board), wherein the electrically conductive plane can be implemented by a copper surface (e.g. V_{cc} or GND) situated on the top or bottom layer. Electronic and mechanical components for implementing a sensor (signal evaluation) and the actuation of the individual dipole elements can be arranged on this circuit board in a very space-saving fashion. This dispenses with connection cables from the antenna structure to evaluation electronics.

Compared to a broadband slot antenna that—in a frequency range between 2.2 and 9 GHz—can have an overall depth of 80 mm or more, the depth in the antenna concept according to the invention is fixed by the spacing between the support structure 18 of the emitter elements 12 and the reflector element 28, and it usually lies in the region of λ/4 at the mid-frequency. In the aforementioned frequency range, this results in a relatively short overall height of e.g. 10 mm (not including the length/height of the supply).

In further embodiments, the reflector 28 of the antenna arrangement can be placed even closer to the dipole elements by implementing the reflector in a magnetically conductive fashion (reflection factor +1) for certain frequency bandwidths by means of electromagnetic band gap structures (EBG structures). Here the reflected wave is in phase with the approaching one, as a result of which the spacing of the structures can be reduced. However, a disadvantage is an increase at each individual dipole in the input reflection factor.

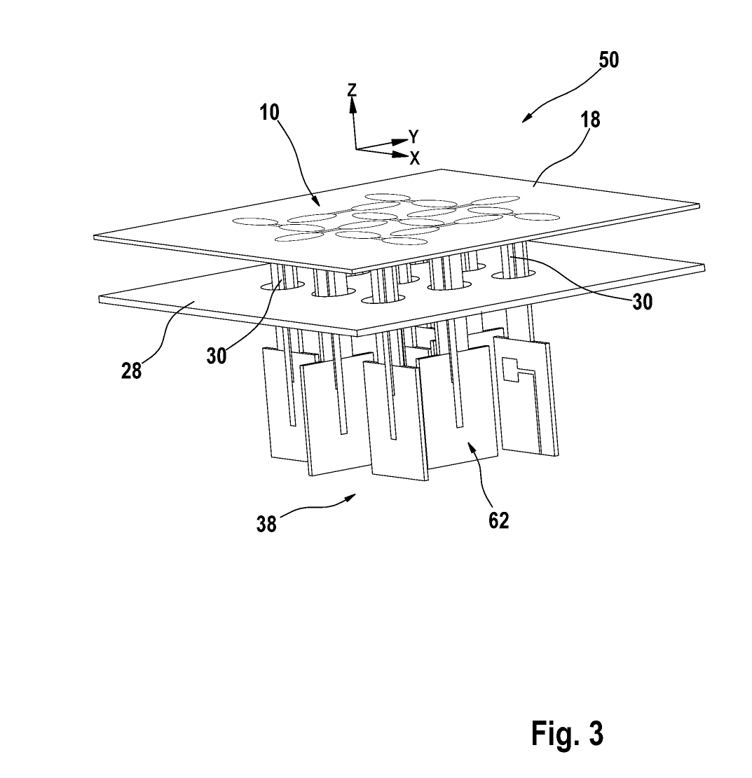

FIG. 2 moreover shows part of the supply structure of the antenna apparatus according to the invention. Supplying the antenna will be discussed in more detail in conjunction with FIG. 3.

FIG. 3 shows a device 50 according to the invention in the form of a dual polarized, ultra-wideband dipole array 10 with a metallic reflector element 28 and Marchand baluns (62) for the supply. Here, the reflector 28 is at a distance of approximately 10 mm from the dipole elements 12. The frequency range of this antenna in the exemplary embodiment according to FIG. 3 is approximately 2.2 GHz-8.5 GHz. The substrate and reflector size is approximately 72 mm×72 mm.

A dipole 12 is supplied via a slotline 30, which projects through the substrate 18 of the dipole elements 12 and is connected to the former in an electrically conductive fashion. At the other end of the slotline 30 there is a balanced supply by means of a Marchand balun (62) (microstrip line on a slotline transition), to which a broadband matching network for transformation from approximately 73 Ohm to the wave resistance of Z_{L}=50 Ohm has additionally been appended.

The distribution of the power to the dipoles in the two preferred directions X and Y is brought about by a power-divider network, which can for example consist of Wilkinson power dividers or tapered power dividers or the like. Overall, two supply ports are available. Port 1 supplies the 4 vertical (Y-direction) dipoles in this exemplary embodiment and port 2 supplies the 5 horizontal (X-direction) dipoles of this exemplary embodiment, wherein sufficient directivity can already be achieved by supply to the 4 outer dipoles.

The array 32 resulting thus moreover has a reflector 28 in order mainly to emit in one half-plane (Z-direction in FIG. 3) only.

In a further embodiment, additional dipole elements, which are directly terminated with the wave resistance Z_{L}=73 Ohm, can be arranged directly next to the supplied and emitting dipole elements 12. This ensures that every supplied dipole 12 is surrounded by the same metallic structures and the input impedance thereof is identical to all additional, supplied dipoles. This reduces the design complexity of the supply (slotline+balancing transmitter) because it is identical for all supplied dipoles.

A dielectric, e.g. a further substrate with the same material thickness, additionally applied to the dipole elements can further lower the lower cut-off frequency of the dipoles and thus further increase the bandwidth of the structure. Whilst having the same dipole dimensions, the structure appears longer in electric terms.

In order to reduce the lateral emission, the array 32 can advantageously be surrounded, laterally and below, by a cavity, for example in the form of a metal surrounding (not illustrated in FIG. 3 for reasons of clarity), or be provided with absorber material. This reduces the influence of laterally situated moving parts on the properties of the antenna (e.g. changing the input impedance).

The increase in directivity of the dual polarized dipole array can be brought about by targeted guidance of the waves in a dielectric waveguide, which is also referred to as a rod for brevity. Here, the dielectric material of the rod is applied on the dipoles. The separation of the waves takes place depending on the resulting wavelength in the front region of the rod, which should have a cylindrical design. As the diameter of the waveguide decreases, waves with higher frequencies are detached.

In a further embodiment, the dipole array can also be implemented on e.g. a dielectric film (e.g. Kapton by DuPont) instead of on a circuit board. The flexibility of this film allows the application of dipole elements including the supply lines; this allows virtually 90 degree angles in the supply lines toward the reflector.

Moreover, it is also possible that a dipole element including supply is formed from a single metal part, e.g. made of copper.

The monitoring region implemented by the array from FIG. 3, which is referred to as array cell 32 below, can be extended by duplicating or multiplying this basic structure. Individual dipole elements or individual dipole cells can be supplied in a targeted fashion as a result of a plurality of array cells placed next to one another and a combinatory logic. The superposition of the fields generated by the dipoles 12 once again result in a new measurement region or measurement spot. Hence the measurement spot wanders along the substrate surface depending on the respectively supplied dipole elements.

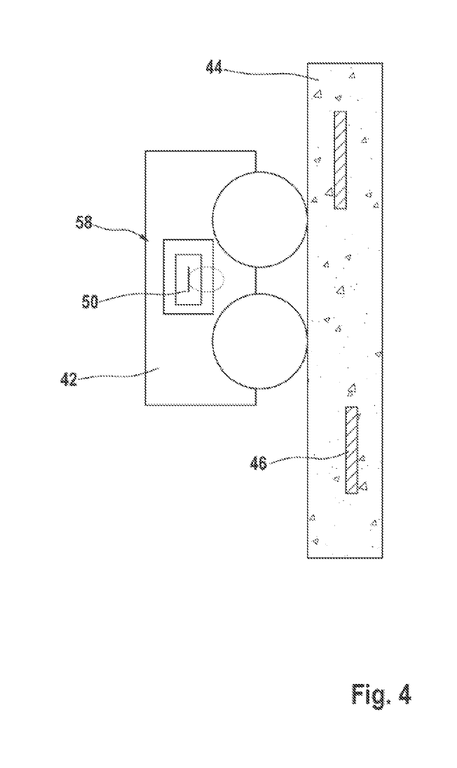

FIG. 4 shows, in a schematic view, a localization and material constant determination instrument 42 with the device 50 according to the invention as a component of a UWB sensor 58. During operation, the measurement instrument is displaced over a wall 44 or another type of material. By way of example, such an instrument 42 makes it possible to localize objects 46 enclosed by a medium or determine material parameters, such as the dampness of a wall 44, as presented in principle in DE 102 07 424 A1, the contents of which should likewise be considered to be disclosed here.

An alternative application of the device according to the invention for transmitting electromagnetic RF signals is offered by the field of protection sensors. Thus, for example, an appropriate antenna structure can be used to realize a detector for “pre-impact detection”.

A further important application of the device according to the invention emerges from the advantage of good focusing and alignability of the measurement signal. This makes it possible to secure more precisely a protection zone to be monitored, for example directly in front of a saw blade or a saw band (cf. FIG. 1).

FIG. 5 shows an exemplary embodiment for a machine-tool monitoring device provided for identifying the presence of a type of material, more particularly tissue such as the human tissue in a hand, using the example of a circular saw 48. The circular saw 48 has an identification device 52, which is provided for identifying the presence of a type of material 54, in particular tissue, in a machine-tool work area 56. The identification device 52 has at least one device 50 according to the invention for transmitting electromagnetic RF signals. The device 50 according to the invention can be installed in a plane above the work area of the machine tool, as indicated in FIG. 5. Alternatively, the device 50 can also be integrated directly into the work table 40. Both options can be implemented both individually and at the same time, as illustrated in FIG. 5 in an exemplary fashion.

As a result of a plurality of array cells 32 placed next to one another, which in particular are arranged in or under the work table 40 of the machine tool, and as a result of a combinatory logic, the antenna structure according to the invention advantageously makes it possible to secure a large-area region around the work means of the machine tool, e.g. a saw blade. The antenna structure according to the invention is advantageous in that the latter can be brought very close to the work means (in this respect, cf. the illustration in FIG. 1) and can at the same time cover a large monitoring region, particularly if use is made of a plurality of array cells 32.

In respect of the underlying measurement method and a possible embodiment of such a machine-tool monitoring device, reference is made to EP 0711 0067 A1, the contents of which should thus likewise be considered disclosed here.

However, the application of the device according to the invention within the scope of a machine-tool monitoring device is not restricted to saws and, in particular, to circular saws.

Moreover, nor is the device according to the invention restricted to the use as a component of a machine-tool monitoring device. In addition to the described use in a localization and material constant determination instrument, a person skilled in the art recognizes the further options for using the device according to the invention.

1. A device for transmitting and/or receiving electromagnetic RF signals, in particular a UWB antenna, with an ultra-wideband, in particular planar, antenna structure, comprising a plurality of dipole elements, wherein each dipole element has two poles with a substantially elliptic basic shape.

2. The device as claimed in claim 1, wherein the dipoles are formed on or in a planar support structure.

3. The device as claimed in claim 1, wherein the axis of each dipole is arranged parallel to one of two preferred directions.

4. The device as claimed in claim 3, wherein the two preferred directions are perpendicular to one another.

5. The device as claimed in claim 3, wherein the two preferred directions run parallel to at least two edges of the support structure.

6. The device as claimed in claim 1, wherein four poles of four adjacent dipoles form an annular structure.

7. The device as claimed in claim 1, wherein a plurality of dipole elements form an array cell.

8. The device as claimed in claim 7, wherein a plurality of array cells are present.

9. The device as claimed in claim 1, wherein the dipole elements are supplied via at least one slotline.

10. The device as claimed in claim 9, wherein at least one Marchand balun is provided for supply, in particular for balanced supply, of the slotline.

11. The device as claimed in claim 1, wherein provision is made for a reflector element that is arranged substantially parallel to the support structure of the dipoles.

12. The device as claimed in claim 11, wherein the spacing between the reflector element and the support structure of the dipoles substantially equals a quarter wavelength at the mid-frequency of the antenna.

13. The device as claimed in claim 11, wherein the reflector element is embodied as a substantially planar, metallic or metalized reflector.

14. The device as claimed in claim 11, wherein the reflector element is formed by a printed circuit board.

15. A measurement instrument, in particular a localization and/or material determination instrument, for determining objects enclosed by a medium and/or for determining material parameters, in particular for determining the dampness of a material, with at least one UWB sensor, wherein the sensor has at least one device as claimed in claim 1.

16. A machine-tool monitoring device with an identification device, which is provided for identifying the presence of a type of material, in particular tissue, in a machine-tool work area, and with a work mechanism, wherein the identification device has a sensor unit with at least one device as claimed in claim 1.

17. The machine-tool monitoring device as claimed in claim 16, wherein the machine tool is a saw, in particular a stand-mounted saw.

18. The machine-tool monitoring device as claimed in claim 16, wherein at least one array cell is arranged adjacent to the work mechanism.

19. The machine-tool monitoring device as claimed in claim 16, wherein a plurality of array cells are arranged around the work mechanism means.
